(19) United States
(12) Patent Application Publication
(10) Pub. No.: US 2026/0188551 A1
(43) Pub. Date: Jul. 2, 2026

(54) MAGNETIC FIELD CANCELLATION BASED ON WIRE ROUTING

(71) Applicant: NVIDIA CORPORATION, Santa Clara, CA (US)

(72) Inventors: Lizhi ZENG, Shenzhen, Guangdong (CN); Chen WANG, Santa Clara, CA (US); Ziyuan ZHENG, Shenzhen, Guangdong (CN); Mengli ZHAO, Shenzhen, Guangdong (CN); Cheng ZHANG, Shenzhen, Guangdong (CN)

(21) Appl. No.: 18/697,917

(22) PCT Filed: Feb. 28, 2024
(86) PCT No.: PCT/CN2024/079106

§ 371 Date: Apr. 2, 2024

(51) Int. Cl. H01F 27/00; H01F 27/24; H01F 27/28; H03H 7/01; H05K 1/181

(52) U.S. Cl. CPC H01F 27/006; H01F 27/24; H01F 27/2823; H01F 27/2847; H03H 7/0115; H05K 1/181; H05K 2201/1003

(57) ABSTRACT

In various embodiments, an inductor package comprises a first portion of an inductor coil that runs substantially along a first axis and carries an electrical current along the first axis in a first direction to produce a first magnetic flux, and a second portion of the inductor coil that runs substantially along the first axis and carries the electrical current along the first axis in a second direction to produce a second magnetic flux that at least partially cancels the first magnetic flux, where the first direction is opposite the second direction.

### BACKGROUND

### Field of the Various Embodiments

The various embodiments relate generally to computer systems and electrical circuits and, more specifically, to magnetic field cancellation based on wire routing.

### Description of the Related Art

Computer devices typically include various electronic circuits to regulate the power delivered to components within those devices and systems during operation. For example, many computing devices include multiple power control circuits. Computing devices typically also include electronic circuits that have differing combinations of resistors (R), inductors (L), and capacitors (“RLC circuits”) for various applications and operations, such as controlling oscillations, filtering, and tuning, to name a few. When designing electronic circuits, designers attempt to minimize parasitic characteristics associated with components making up the electronic circuits, such as the inductors included in a RLC circuit. However, high-performance computer devices, such as laptops, desktops, motherboards having high-performance integrated circuits and other high-performance components, and graphical processing units (GPUs), consume large amounts of power and therefore require large inductors with high current ratings to control the power drawn by those devices during operation. Consequently, designers oftentimes select power inductors with high-current ratings for use in high-performance computer devices.

However, one characteristic of power inductors with high-current ratings is that using these type of power inductors can create substantial magnetic flux leakage that can cause electromagnetic interference (EMI) problems with respect to the other electronic components within a computer device or system. For example, conducted emission failures can result from the electromagnetic interference caused by magnetic flux spreading to various electronic components within a computer device via connected power lines or communication lines. These types of failures can prevent the computer device from satisfying electromagnetic compatibility regulatory requirements.

To mitigate electromagnetic interference caused by magnetic flux leakage, designers sometimes try to ensure that there are adequate distances between the inductors and the other electronic components within a computer device oftentimes add additional materials to the other electronic components, such as absorbent material or metal covers, to block the effects of any magnetic flux leakage that may occur during operation. These preventative measures, however, can increase form factors when using inductors made with low magnetic permeability materials. Accordingly, in other approaches, designers attempt to address magnetic flux leakage issues by adding other structures, such as heatsinks to the circuit, as well as EMI clips to connect the heatsinks to the inductors. These types of additional structures can act to reduce the amount of magnetic flux emanating from the inductor packages in a computer device. However, one drawback of using additional structures is that conventional heatsinks and EMI clips oftentimes are not terribly effective, given that heatsinks can also create electromagnetic interference that can inhibit the operation of other components with the computer device. Further, adding additional components increases the footprint size of the inductors within a computer device, which reduces the number of inductors that can be included in a given computer device.

As the foregoing illustrates, what is needed in the art are more effective designs for the inductors implemented in high-performance computer devices.

### SUMMARY

In various embodiments, an inductor package comprises a first portion of an inductor coil that runs substantially along a first axis and carries an electrical current along the first axis in a first direction to produce a first magnetic flux, and a second portion of the inductor coil that runs substantially along the first axis and carries the electrical current along the first axis in a second direction to produce a second magnetic flux that at least partially cancels the first magnetic flux, where the first direction is opposite the second direction

In various embodiments, a printed circuit board assembly comprises a printed circuit board (PCB) layer, and an inductor package that is arranged on the PCB layer, the inductor package comprising a first portion of an inductor coil that runs substantially along a first axis and carries an electrical current along the first axis in a first direction to produce a first magnetic flux, and a second portion of the inductor coil that runs substantially along the first axis and carries the electrical current along the first axis in a second direction to produce a second magnetic flux that at least partially cancels the first magnetic flux, where the first direction is opposite the second direction.

At least one technical advantage of the disclosed design relative to the prior art is that, with the disclosed design, a printed circuit board assembly or inductor package includes an inductor coil comprised of complementary coil section pairs that are arranged to limit the magnetic flux that leaks from inductor coil. In particular, by arranging portions of inductor in parallel and directing the electrical current to flow in opposite directions through the respective portions, the respective portions produce magnetic fluxes in opposing directions. Circuits that use inductors comprised of the complementary coil section pairs can drive the inductor with large currents without causing a large magnetic flux. Consequently, the disclosed design enables a greater density of inductors to be included in a computer device, such as a printed circuit board, relative to what can be achieved using prior art designs. Further, with the disclosed design, individual inductors and inductor packages can be located closer to the other components in a computer device relative to what can be achieved using prior art designs. Accordingly, the disclosed design can improve the ability of a high-performance computing devices to control power use during operation. These technical advantages represent one or more technological improvements over prior art approaches and designs.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 illustrates a switched mode power supply circuit that includes an exemplar inductor, according to various embodiments.

FIG. 2 illustrates an exemplar inductor coil arranged to produce cancelling magnetic fields, according to various embodiments.

FIG. 3 illustrates an exemplar inductor coil with round conducting material arranged to produce cancelling magnetic fields, according to various embodiments.

FIG. 4 illustrates an exemplar inductor coil including multiple complementary coil section pairs arranged to produce cancelling magnetic fields, according to various embodiments.

FIG. 5 compares the inductor package of FIG. 2 with an inductor package of another embodiment.

FIG. 6 is a block diagram of a computer system configured to implement one or more aspects of the various embodiments.

### DETAILED DESCRIPTION

In the following description, numerous specific details are set forth to provide a more thorough understanding of the various embodiments. However, it will be apparent to one skilled in the art that the inventive concepts may be practiced without one or more of these specific details.

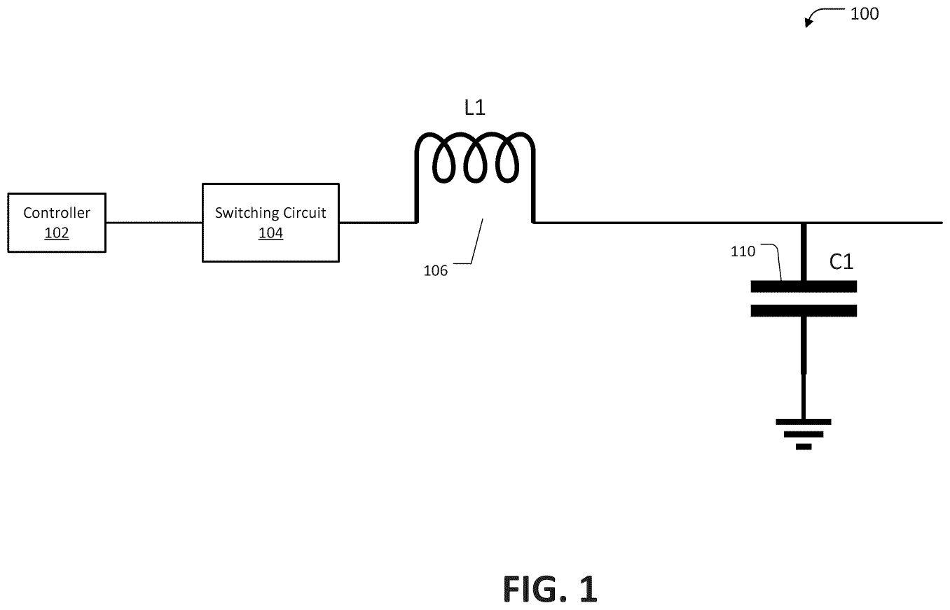

FIG. 1 illustrates a switched mode power supply circuit 100 that includes an exemplar inductor pair 120, according to various embodiments. As shown, the switched mode power supply circuit 100 includes, without limitation, a controller 102, a switching circuit 104, an inductor 106, and a capacitor 110.

The switched mode power supply (SMPS) circuit 100 is configured to receive an input voltage Vᵢₙ and provide an output voltage Vout to a load. In various embodiments, SMPS circuit 100 includes a controller 102 that controls one or more switching circuits 104 to control when the inductor 106 is connected to the input voltage. For example, the topology of the inductors in relation to the capacitor 110 and a resistor (not shown) can be modified such that the SMPS circuit 100 is a buck converter, a boost converter, a buck-boost converter, and so forth. The SMPS circuit 100 can be used to provide a consistent output voltage to a connected load.

In some examples, the load is an electronic component, such as a processor, a memory, a semiconductor, such as a central processing unit (CPU), a graphics processing unit (GPU), a high-current application-specific integrated circuit (ASIC), and/or a field programmable gate array (FPGA), incorporated in a computer device or system. As persons skilled in the art will appreciate, a computing device or system that includes the load powered by the SMPS circuit 100 can be any type of technically feasible computer system, including, without limitation, a server machine, a server platform, a desktop machine, a laptop machine, a hand-held/mobile device, or a wearable device. Furthermore, persons skilled in the art will understand that the SMPS circuit 100 can also be used to power other types of components.

The switching circuit 104 includes a plurality of switches that control a current that is provided to the inductors 106. In some embodiments, the switches can include one or more transistors, such as n-type or p-type metal-oxide-semiconductor field-effect transistor (MOSFETs) that open or close based on the PWM signal to enable a current to flow to the connected inductor 106. The driver controls the operation of each switch in the plurality of switches in accordance with control signals, such as a pulse width modulation (PWM) control signal generated by the controller 102. In some embodiments, the switching circuit 104 can be driver and MOSFET combination (DrMOS) that includes power drivers for the plurality of MOSFETs included in the switching circuit 104.

In various embodiments, the SMPS circuit 100 includes one or more additional phases, where each phase includes an additional switching circuit (e.g., 104(2), etc.) and an additional inductor (e.g., 106(2), etc.). In such instances, each switching circuit in the plurality of switching circuits 104 generates a different phase of the output voltage Vout by driving a one of the plurality of inductors 106 at different times of a duty cycle. The switching circuit 104 includes a driver and a plurality of switches that respond to a signal that the controller 102 provides.

When a switch that is coupling the inductor 106 to the input voltage Vᵢₙ is turned ON, or closed, the switching circuit 104 is coupled to the input voltage Vᵢₙ such that the switching circuit 104 causes the inductor 106 to generate the output voltage Vout. When the switch is turned OFF, or is open, the switching circuit 104 is disconnected from the input voltage Vᵢₙ and the voltage is not generated by the inductor 106. When another switch is turned ON, the switching circuit 104 is coupled to ground, and when turned OFF, the switching circuit 104 is disconnected from ground. In the illustrated example of FIG. 1, the switching circuit 104 includes two switches and one driver. However, in some embodiments, the switching circuit 104 includes a different number of switches and/or drivers.

The controller 102 generates one or more control signals for controlling operation of the switching circuit 104. In some embodiments, the controller 102 generates the control signal based on measurements indicative of and/or associated with voltages and/or currents flowing through the SMPS circuit 100. For example, the controller 102 can generate one or more PWM signals based on measurements indicative of and/or associated with currents flowing through the SMPS circuit 100. In operation, the controller 102 applies the one or more control signals to the drivers included in the switching circuit 104 to control the frequency and/or the duty cycle at which the switches included in the switching circuit 104 are turned ON and OFF. The controller 102 can be implemented as any suitable control device and/or circuit for controlling operation of switching circuits 110. For example, the controller 102 can be implemented as one or more of an analog control circuit, a digital control circuit, a microprocessor, an integrated circuit, and/or any other suitable control device for controlling operation of the switching circuit 104. As another example, the controller 102 controls PWM signals based on the output voltage and/or the output current.

The inductor (L1) 106 is coupled to the output of the switching circuit 104 such that the current i generated by the respective switching circuit 104 flows through the inductor 106 to provide the output voltage. In various embodiments, the inductor 106 has varying characteristics that affect the operation of the SMPS circuit 100. For example, the inductor 106 that is based on a core type, the number of turns in the inductor coil, a coil type, a coil shape, and so forth. In some embodiments, the core of the inductors 106 is an air core, a rod-like core, or a drum-like core. Other shapes for the core of the inductor 106 are possible. For example, the core of the inductor 106 can be a toroid, a block, etc. Additionally or alternatively, the inductor 106 can include a coil around the core. In such instances, the coil shape can differ from the shape of the core.

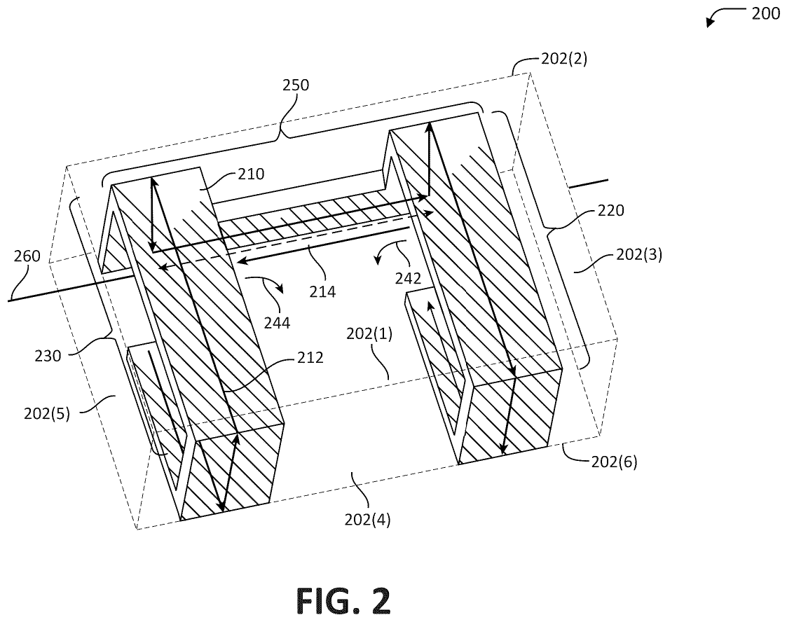

As will be discussed in further detail in relation FIGS. 2-4, the coil of the inductor 106 can be physically arranged to reduce magnetic flux that leaks from the inductor 106. For example, a portion of the inductor 106 carries an electric current in a first direction, producing a first magnetic field, while a separate portion of the inductor 106 carries the electric current in a second direction that is substantially opposite that of the first direction. The current produces a second magnetic field. The first magnetic field and the second magnetic field engage in active magnetic field cancellation, lowering the magnetic field produced by the inductor 106. In such instances, the magnetic flux at locations proximate to the inductor 106 is lowered, as the magnetic fields produced by the respective at least partially cancel out.

FIG. 2 illustrates an exemplar inductor coil 210 arranged to produce cancelling magnetic fields, according to various embodiments. As shown, the inductor package 200 includes, without limitation, a set of walls 202 (e.g., 202(1)-202(6)) and the inductor coil 210. The inductor coil 210 includes, without limitation, a first portion 220, a second portion 230, and a connecting portion 250.

In various embodiments, an inductor package 200 includes and inductor coil that includes multiple turns. For example, the inductor coil 210 comprises a flat electrical wire, such as an insulated magnet wire. The inductor package 200 includes one or more pads to connect the inductor coil 210 to separate electronic components. In operation, the controller 102 drives the switching circuit 104 to connect the input voltage to the respective inductor coil 210. When a current 212 flows through the inductor coil 210, the current flow generates a leakage magnetic field that emanates from the inductor coil 210.

The first portion 220 and the second portion 230 form a complementary coil section pair. In some embodiments, the connecting portion 250 forms a complementary pair with an electrical wire 260 outside of the inductor package 200. Due to the wire routing through the respective portions 220, 230, 250 of the inductor coil 210, the current flow 212 causes the shape in portions of the magnetic field to differ. For example, the magnetic field 242 rotates around the first portion 220 and the magnetic field 244 rotates around the second portion 230 in opposite directions. Due to the physical arrangement of the wire routing in the first portion 220 and the second portion 230, the magnetic fields 242, 244 perform active magnetic field cancellation, lowering or cancelling the magnetic flux emanating from inductor coil 210. In various embodiments, the first portion 220 and the second portion 230 of the inductor coil 210 have matching physical characteristics (e.g., same material, same length, same thickness, etc.). In such instances the first portion 220 and the second portion 230 each produce magnetic fields 242, 244 of equal intensity. The magnetic fields 242, 244 are in opposite directions, with the second magnetic field 244 counteracting the first magnetic field 242. Consequently, the magnetic flux experienced at locations proximate to the inductor package 200 is lowered or cancelled due to the opposing magnetic fields 242, 244.

In various embodiments, the inductor package 200 is fixed to a printed circuit board (PCB) assembly (not shown) that is designed to connect a large quantity of electronic components to perform various tasks. As persons skilled in the art will understand, the disclosed designs can be used with various inductor coils 210 and/or inductor packages 200 and therefore, can be used across a wide variety of applications, including, and without limitation, various types of desktops, laptops, workstations, servers, medical devices, automotive devices, and/or robots. In various embodiments, the inductor package 200 is fixed to a PCB layer that includes one or more electrical wires 260. Additionally or alternatively, the connecting portions 250 of the inductor coil are configured to be positioned proximate to the electrical wire 260. In such instances, the PCB assembly can be configured to carry a return current 214 in an opposite direction of the electrical current that the connecting portion 250 of the inductor coil 210 is carrying. In such instances, the electrical currents 212, 214 flow in opposite directions, generating counteracting magnetic fields in a direction that is perpendicular to the counteracting magnetic fields 242, 244.

In various embodiments, the inductor package 200 occupies a smaller area than conventional inductor packages. For example, the inductor package 200 can be unshielded, whereas various conventional inductor packages include thick shielding layers to attenuate the magnetic fields generated by an inductor. Further, the inductor package 200 can be located proximate to other components, as magnetic flux leakage is mitigated or cancelled due to the physical configuration of the inductor coil 210. The additional density on such a PCB assembly afforded by the inductor package 200 improves the ability to control power use on the PCB assembly.

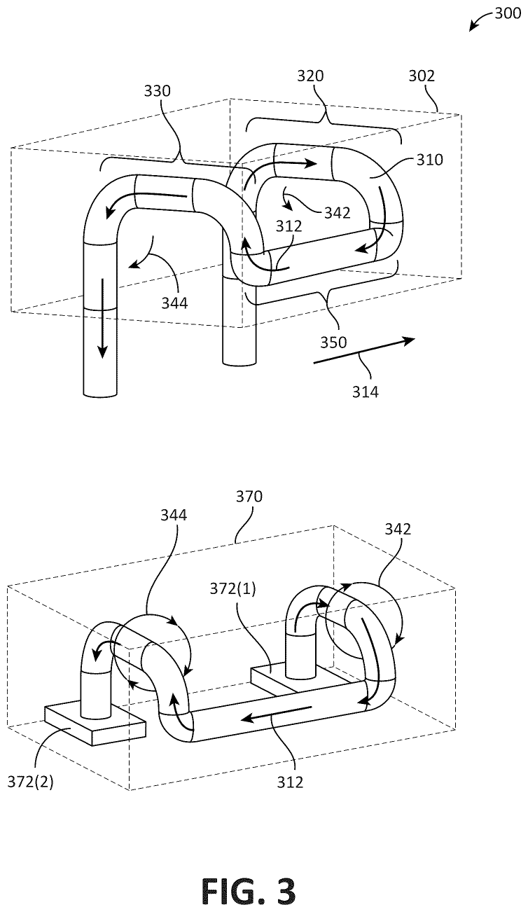

FIG. 3 illustrates an exemplar inductor coil 310 with round conducting material arranged to produce cancelling magnetic fields, according to various embodiments. As shown, the inductor package 300 includes, without limitation, a set of walls 302, a first portion 320, a second portion 330, and connecting portion 350.

The physical arrangement of the inductor package 300 and the inductor coil 310 is similar to the physical arrangement of the inductor package 200 and the inductor coil 210. As shown, the inductor coil 310 comprises a round electrical wire, such as an insulated magnet wire.

Due to the wire routing through the respective portions 320, 330, 350 of the inductor coil 310, the current flow 312 causes the shape in portions of the magnetic field to differ. For example, the magnetic field 342 rotates around the first portion 320 and the magnetic field 344 rotates around the second portion 330 in opposite directions. Due to the physical arrangement of the wire routing in the first portion 320 and the second portion 330, the magnetic fields 342, 344 perform active magnetic field cancellation, lowering or cancelling the magnetic flux emanating from inductor coil 310. Additionally or alternatively, the inductor package 300 can be fixed on a PCB board assembly that includes an electrical wire carrying a return current 314. In such instances, the electrical currents 312, 314 flow in opposite directions, generating counteracting magnetic fields in a direction that is perpendicular to the counteracting magnetic fields 342, 344.

In various embodiments, the inductor package 370 is similar to the inductor package 300. The inductor package 370 includes a set of contact pads 372(1)-372(2) to connect the inductor coil 310 to separate electronic components.

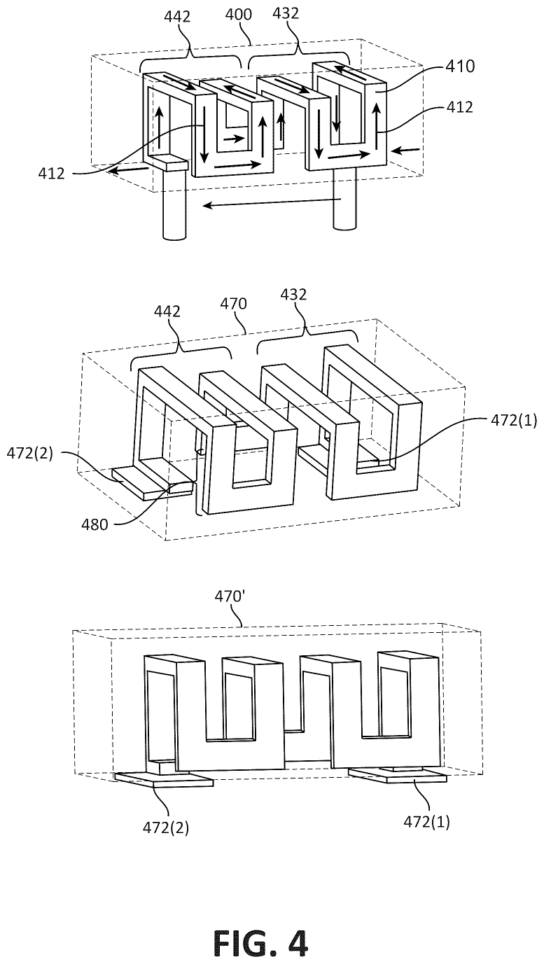

FIG. 4 illustrates an exemplar inductor coil 410 including multiple complementary coil section pairs 432, 442 arranged to produce cancelling magnetic fields, according to various embodiments. As shown, the inductor package 400 includes, without limitation, an inductor coil 410. The inductor coil 410 includes, without limitation, a first complementary coil section pair 432 and a second complementary coil section pair 442.

The physical arrangement of the inductor package 400 and the inductor coil 410 is similar to the physical arrangement of the inductor packaged 200, 300 and the inductor coils 210, 310. As shown, the inductor coil 310 includes multiple turns. For example, the inductor coil 410 includes a first complementary coil section pair 432 that includes a first portion and a second portion where the current 412 flows in opposite directions. The inductor coil 410 includes a second complementary coil section pair 442 that includes a third portion and a fourth portion where the current 412 flows in opposite directions. In various embodiments, the inductor package 400 can include N additional complementary coil section pairs.

In various embodiments, the inductor package 470 is similar to the inductor package 400. As shown, the inductor package 470 includes a set of contact pads 472(1)-472(2) to connect the inductor coil 410 to separate electronic components.

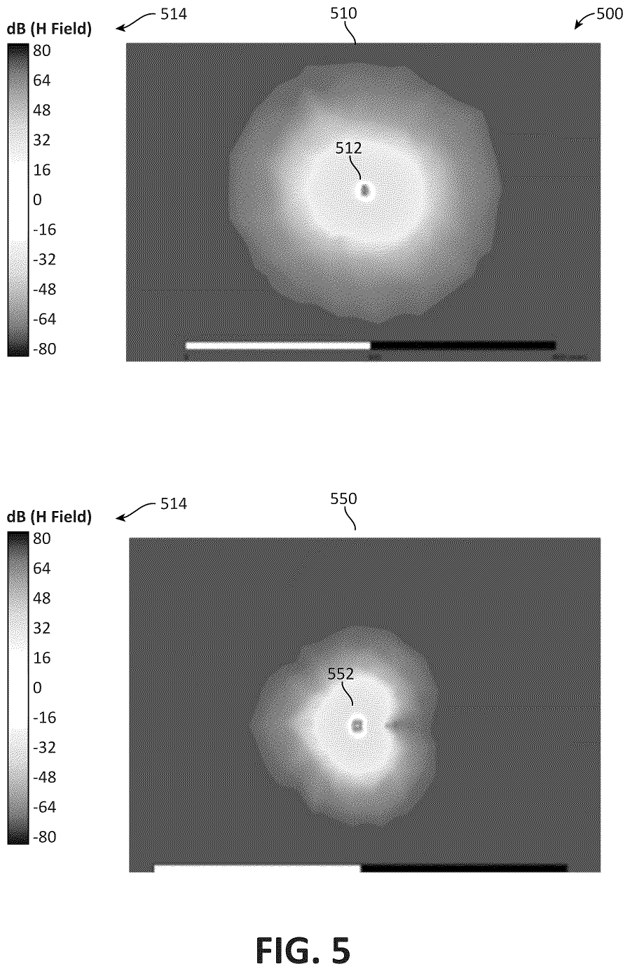

FIG. 5 illustrates graphs 500 of the magnetic fluxes produced by two types of inductor packages, according to various embodiments. As shown, and without limitation, the graphs 500 include a magnetic flux graph 510 for an inductor package 512 that contains no complementary coil section pairs and a magnetic flux graph 550 for an inductor package 552 that includes at least one complementary coil section pair.

The magnetic flux graph 510 is a simulation of the inductor package 512 when producing a magnetic field. As shown, the inductor package 512 produces a magnetic field and associated magnetic flux whose intensity dissipates over distance from the inductor package 512. As indicated by the legend 514, the inductor package 512 initially produces a magnetic field with a magnetic field intensity (H) of 60 dB, gradually dissipating to −48 dB a distance away from the inductor package 512.

The magnetic flux graph 550 is a simulation of the inductor package 552 in operation. As shown, the inductor package 552 produces a magnetic field and associated magnetic flux whose intensity dissipates over distance from the inductor package 552. As indicated by the legend 414, the magnetic field intensity (H) of the inductor package 552 quickly dissipates to −80 dB over a similar distance to the magnetic field produced by the inductor package 512.

The complementary coil section pairs in the inductor package 552, which is included in the inductor coil 210, thus effectively decreases the magnetic field intensity by approximately 16 dB, indicating an increased effectiveness in the magnetic flux cancellation performed by complementary coil section pairs in the inductor coil 210.

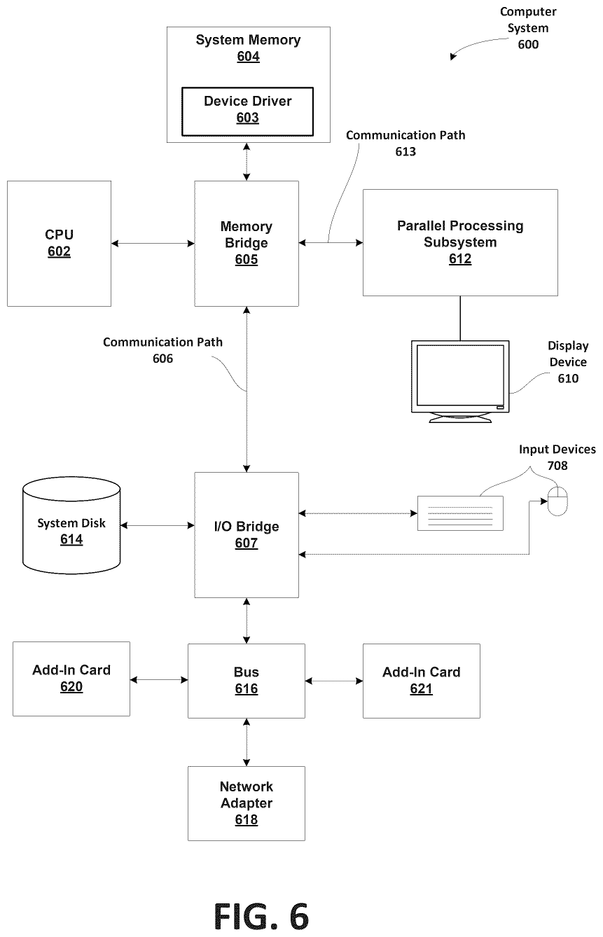

FIG. 6 is a block diagram of a computer system configured to implement one or more aspects of the various embodiments. As shown, computer system 600 includes, without limitation, a central processing unit (CPU) 602 and a system memory 604 coupled to a parallel processing subsystem 612 via a memory bridge 605 and a communication path 613. Memory bridge 605 is further coupled to an I/O (input/output) bridge 607 via a communication path 606, and I/O bridge 607 is, in turn, coupled to a bus 616.

In various embodiments, one or more components of the computer system 600 (e.g., the CPU 602, the parallel processing subsystem 612, etc.) includes one or more circuit boards that incorporate one or more of the inductor packages 200, 300, 400 as part of the circuitry. For example, a circuit board containing the CPU 602 can include one or more switching power circuits that include at least one inductor package 200, 300, 400.

In operation, I/O bridge 607 is configured to receive user input information from input devices 608, such as a keyboard or a mouse, and forward the input information to CPU 602 for processing via communication path 606 and memory bridge 605. Bus 616 is configured to provide connections between I/O bridge 607 and other components of the computer system 600, such as a network adapter 618 and various add-in cards 620 and 621.

As also shown, I/O bridge 607 is coupled to a system disk 614 that may be configured to store content and applications and data for use by CPU 602 and parallel processing subsystem 612. As a general matter, system disk 614 provides non-volatile storage for applications and data and may include fixed or removable hard disk drives, flash memory devices, and CD-ROM (compact disc read-only-memory), DVD-ROM (digital versatile disc-ROM), Blu-ray, HD-DVD (high-definition DVD), or other magnetic, optical, or solid-state storage devices. Finally, although not explicitly shown, other components, such as universal serial bus or other port connections, compact disc drives, digital versatile disc drives, film recording devices, and the like, may be connected to I/O bridge 607 as well.

In various embodiments, memory bridge 605 may be a Northbridge chip, and I/O bridge 607 may be a Southbridge chip. In addition, communication paths 606 and 613, as well as other communication paths within computer system 600, may be implemented using any technically suitable protocols, including, without limitation, AGP (Accelerated Graphics Port), HyperTransport, or any other bus or point-to-point communication protocol known in the art.

In some embodiments, parallel processing subsystem 612 comprises a graphics subsystem that delivers pixels to a display device 610 that may be any conventional cathode ray tube, liquid crystal display, light-emitting diode display, or the like. In such embodiments, the parallel processing subsystem 612 incorporates circuitry optimized for graphics and video processing, including, for example, video output circuitry. Such circuitry may be incorporated across one or more parallel processing units (PPUs) included within parallel processing subsystem 612. In other embodiments, the parallel processing subsystem 612 incorporates circuitry optimized for general purpose and/or compute processing. Again, such circuitry may be incorporated across one or more PPUs included within parallel processing subsystem 612 that are configured to perform such general purpose and/or compute operations. In yet other embodiments, the one or more PPUs included within parallel processing subsystem 612 may be configured to perform graphics processing, general purpose processing, and compute processing operations. System memory 604 includes at least one device driver 603 configured to manage the processing operations of the one or more PPUs within parallel processing subsystem 612. The system memory 604 also includes any number of software applications 625 that execute on the CPU 602 and may issue commands that control the operation of the PPUs.

In various embodiments, parallel processing subsystem 612 may be integrated with one or more other the other elements of FIG. 6 to form a single system. For example, parallel processing subsystem 612 may be integrated with CPU 602 and other connection circuitry on a single chip to form a system on chip (SoC).

It will be appreciated that the system shown herein is illustrative and that variations and modifications are possible. The connection topology, including the number and arrangement of bridges, the number of CPUs 602, and the number of parallel processing subsystems 612, may be modified as desired. For example, in some embodiments, system memory 604 could be connected to CPU 602 directly rather than through memory bridge 605, and other devices would communicate with system memory 604 via memory bridge 605 and CPU 602. In other alternative topologies, parallel processing subsystem 612 may be connected to I/O bridge 607 or directly to CPU 602, rather than to memory bridge 605. In still other embodiments, I/O bridge 607 and memory bridge 605 may be integrated into a single chip instead of existing as one or more discrete devices. Lastly, in certain embodiments, one or more components shown in FIG. 6 may not be present. For example, bus 616 could be eliminated, and network adapter 618 and add-in cards 620, 621 would connect directly to I/O bridge 607.

In sum, an inductor coil is physically arranged in an inductor package or on a printed circuit board. The inductor coil includes a first portion that runs substantially along a first axis. The inductor coil also includes a second portion that runs substantially along the first axis. When an electric current flows through the inductor coil, the current flows through the first portion in a first direction and flows through the second portion in the opposite direction. The current flow in the first portion generates a first magnetic field and the current flows through the second portion to generate a second magnetic field. Due to the physical arrangement of the first portion and the second portion of the inductor coil, the first magnetic field and second magnetic field are generated in opposite directions and perform active magnetic field cancellation. The active magnetic field cancellation causes the magnetic flux experienced at a given location proximate to the inductor coil to be cancelled or substantially reduced.

At least one technical advantage of the disclosed design relative to the prior art is that, with the disclosed design, a printed circuit board assembly or inductor package includes an inductor coil comprised of complementary coil section pairs that are arranged to limit the magnetic flux that leaks from inductor coil. In particular, by arranging portions of inductor in parallel and directing the electrical current to flow in opposite directions through the respective portions, the respective portions produce magnetic fluxes in opposing directions. Circuits that use inductors comprised of the complementary coil section pairs can drive the inductor with large currents without causing a large magnetic flux. Consequently, the disclosed design enables a greater density of inductors to be included in a computer device, such as a printed circuit board, relative to what can be achieved using prior art designs. Further, with the disclosed design, individual inductors and inductor packages can be located closer to the other components in a computer device relative to what can be achieved using prior art designs. Accordingly, the disclosed design can improve the ability of a high-performance computing devices to control power use during operation. These technical advantages represent one or more technological improvements over prior art approaches and designs.

1. In various embodiments, an inductor package comprises a first portion of an inductor coil that runs substantially along a first axis and carries an electrical current along the first axis in a first direction to produce a first magnetic flux, and a second portion of the inductor coil that runs substantially along the first axis and carries the electrical current along the first axis in a second direction to produce a second magnetic flux that at least partially cancels the first magnetic flux, where the first direction is opposite the second direction.

2. The inductor package of clause 1, further comprising a first connecting portion of the inductor coil that connects the first portion to the second portion, where the first connecting portion runs substantially along a second axis perpendicular to the first axis, and carries the electrical current along the second axis in a third direction to produce a third magnetic flux.

3. The inductor package of clause 1 or 2, where the inductor package is arranged on a printed circuit board (PCB) layer of a PCB board assembly, and the PCB layer includes electrical wiring that runs substantially along the second axis parallel to the first connecting portion and carries the electrical current along the second axis in a fourth direction to produce a fourth magnetic flux that at least partially cancels the third magnetic flux, and the fourth direction is opposite the third direction.

4. The inductor package of any of clauses 1-3, where the inductor coil includes a plurality of coil section pairs, and a first coil section pair of the plurality of coil section pairs includes the first portion and the second portion.

5. The inductor package of any of clauses 1-4, further comprising a second coil section pair included in the plurality of coil section pairs, the second coil section pair comprising a first connecting portion of the inductor coil that connects the first portion to the second portion, and a second connecting portion of the inductor coil that connects the second portion to at least a third portion of the inductor coil, where the first connecting portion and the second connecting portion run substantially along a second axis perpendicular to the first axis.

6. The inductor package of any of clauses 1-5, where the inductor package is unshielded.

7. The inductor package of any of clauses 1-6, where the second magnetic flux reduces the first magnetic flux by at least 10 dB.

8. The inductor package of any of clauses 1-7, where at least the inductor coil surrounds a rod core or a drum core.

9. The inductor package of any of clauses 1-8, where the first portion and the second portion of the inductor coil comprises flat conducting wire.

10. The inductor package of any of clauses 1-9, where the first portion and the second portion of the inductor coil comprises round conducting wire.

11. In various embodiments, a printed circuit board assembly comprises a printed circuit board (PCB) layer, and an inductor package that is arranged on the PCB layer, the inductor package comprising a first portion of an inductor coil that runs substantially along a first axis and carries an electrical current along the first axis in a first direction to produce a first magnetic flux, and a second portion of the inductor coil that runs substantially along the first axis and carries the electrical current along the first axis in a second direction to produce a second magnetic flux that at least partially cancels the first magnetic flux, where the first direction is opposite the second direction.

12. The printed circuit board assembly of clause 11, where the inductor package further comprises a first connecting portion of the inductor coil that connects the first portion to the second portion, where the first connecting portion runs substantially along a second axis perpendicular to the first axis, and carries the electrical current along the second axis in a third direction to produce a third magnetic flux.

13. The printed circuit board assembly of clause 11 or 12, where the PCB layer further includes electrical wiring that runs substantially along the second axis parallel to the first connecting portion and carries the electrical current along the second axis in a fourth direction to produce a fourth magnetic flux that at least partially cancels the third magnetic flux, where the fourth direction is opposite the third direction.

14. The printed circuit board assembly of any of claims 11-13, where the inductor coil includes a plurality of coil section pairs, and a first coil section pair of the plurality of coil section pairs includes the first portion and the second portion.

15. The printed circuit board assembly of any of clauses 11-14, where the inductor coil further comprises a second coil section pair included in the plurality of coil section pairs, the second coil section pair comprising a first connecting portion of the inductor coil that connects the first portion to the second portion, and a second connecting portion of the inductor coil that connects the second portion to at least a third portion of the inductor coil, where the first connecting portion and the second connecting portion run substantially along a second axis perpendicular to the first axis.

16. The printed circuit board assembly of any of clauses 11-15, where the inductor package is unshielded.

17. The printed circuit board assembly of any of clauses 11-16, where the second magnetic flux reduces the first magnetic flux by at least 10 dB.

18. The printed circuit board assembly of any of clauses 11-17, where the inductor package includes a rod core or a drum core.

19. The printed circuit board assembly of any of clauses 11-18, where the first portion and the second portion of the inductor coil comprises flat conducting wire or round conducting wire.

20. The printed circuit board assembly of any of clauses 11-19, where the inductor coil is included in one of an oscillator, a filter, a boost converter, a buck converter, a boost-buck converter, or a switched mode power supply (SMPS) circuit.

Any and all combinations of any of the claim elements recited in any of the claims and/or any elements described in this application, in any fashion, fall within the contemplated scope of the present invention and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

While the preceding is directed to embodiments of the present disclosure, other and further embodiments of the disclosure may be devised without departing from the basic scope thereof, and the scope thereof is determined by the claims that follow.

What is claimed is:

1. An inductor package comprising:
a first portion of an inductor coil that runs substantially along a first axis and carries an electrical current along the first axis in a first direction to produce a first magnetic flux; and
a second portion of the inductor coil that runs substantially along the first axis and carries the electrical current along the first axis in a second direction to produce a second magnetic flux that at least partially cancels the first magnetic flux,
wherein the first direction is opposite the second direction.

2. The inductor package of claim 1, further comprising:
a first connecting portion of the inductor coil that connects the first portion to the second portion,
wherein the first connecting portion runs substantially along a second axis perpendicular to the first axis, and carries the electrical current along the second axis in a third direction to produce a third magnetic flux.

3. The inductor package of claim 2, wherein:
the inductor package is arranged on a printed circuit board (PCB) layer of a PCB board assembly; and
the PCB layer includes electrical wiring that runs substantially along the second axis parallel to the first connecting portion and carries the electrical current along the second axis in a fourth direction to produce a fourth magnetic flux that at least partially cancels the third magnetic flux, and
the fourth direction is opposite the third direction.

4. The inductor package of claim 1, wherein:
the inductor coil includes a plurality of coil section pairs, and
a first coil section pair of the plurality of coil section pairs includes the first portion and the second portion.

5. The inductor package of claim 4, further comprising a second coil section pair included in the plurality of coil section pairs, the second coil section pair comprising:
a first connecting portion of the inductor coil that connects the first portion to the second portion; and
a second connecting portion of the inductor coil that connects the second portion to at least a third portion of the inductor coil,
wherein the first connecting portion and the second connecting portion run substantially along a second axis perpendicular to the first axis.

6. The inductor package of claim 1, wherein the inductor package is unshielded.

7. The inductor package of claim 1, wherein the second magnetic flux reduces the first magnetic flux by at least 10 dB.

8. The inductor package of claim 1, wherein at least the inductor coil surrounds a rod core or a drum core.

9. The inductor package of claim 1, wherein the first portion and the second portion of the inductor coil comprises flat conducting wire.

10. The inductor package of claim 1, wherein the first portion and the second portion of the inductor coil comprises round conducting wire.

11. A printed circuit board assembly comprising:
a printed circuit board (PCB) layer; and
an inductor package that is arranged on the PCB layer, the inductor package comprising:
a first portion of an inductor coil that runs substantially along a first axis and carries an electrical current along the first axis in a first direction to produce a first magnetic flux; and
a second portion of the inductor coil that runs substantially along the first axis and carries the electrical current along the first axis in a second direction to produce a second magnetic flux that at least partially cancels the first magnetic flux,
wherein the first direction is opposite the second direction.

12. The printed circuit board assembly of claim 11, wherein the inductor package further comprises:
a first connecting portion of the inductor coil that connects the first portion to the second portion,
wherein the first connecting portion runs substantially along a second axis perpendicular to the first axis, and carries the electrical current along the second axis in a third direction to produce a third magnetic flux.

13. The printed circuit board assembly of claim 12, wherein the PCB layer further includes:
electrical wiring that runs substantially along the second axis parallel to the first connecting portion and carries the electrical current along the second axis in a fourth direction to produce a fourth magnetic flux that at least partially cancels the third magnetic flux,
wherein the fourth direction is opposite the third direction.

14. The printed circuit board assembly of claim 11, wherein:
the inductor coil includes a plurality of coil section pairs, and
a first coil section pair of the plurality of coil section pairs includes the first portion and the second portion.

15. The printed circuit board assembly of claim 14, wherein the inductor coil further comprises a second coil section pair included in the plurality of coil section pairs, the second coil section pair comprising:
a first connecting portion of the inductor coil that connects the first portion to the second portion; and
a second connecting portion of the inductor coil that connects the second portion to at least a third portion of the inductor coil,
wherein the first connecting portion and the second connecting portion run substantially along a second axis perpendicular to the first axis.

16. The printed circuit board assembly of claim 11, wherein the inductor package is unshielded.

17. The printed circuit board assembly of claim 11, wherein the second magnetic flux reduces the first magnetic flux by at least 10 dB.

18. The printed circuit board assembly of claim 11, wherein the inductor package includes a rod core or a drum core.

19. The printed circuit board assembly of claim 11, wherein the first portion and the second portion of the inductor coil comprises flat conducting wire or round conducting wire.

20. The printed circuit board assembly of claim 11, wherein the inductor coil is included in one of an oscillator, a filter, a boost converter, a buck converter, a boost-buck converter, or a switched mode power supply (SMPS) circuit.
